(19) United States
(12) Patent Application Publication
(10) Pub. No.: US 2003/0095505 A1
(43) Pub. Date: May 22, 2003

(54) Cable redundancy in network data links

(76) Inventors: Owen N. Wells, Stanardsville, VA (US); William T. Tunis, Earlysville, VA (US)

Correspondence Address: DYKEMA GOSSETT PLLC, 39577 WOODWARD AVENUE, SUITE 300, BLOOMFIELD HILLS, MI, 48304-5086, US

(21) Appl. No.: 09/991,462

(22) Filed: Nov. 16, 2001

(51) Int. Cl. G01R 31/08; G06F 11/00; G08C 15/00; H04J 1/16; H04J 3/14

(52) U.S. Cl. 370/242; 370/225

(57) ABSTRACT

An autonomous circuit, which may be embedded in a network product or standalone external to the network product, that routes the transmit and receive signals from the network node onto either a primary network cable or a secondary network cable. Determination of which cable to use for communication is made by monitoring activity on either the cable currently in use or on both cables at all times, and switching over to the alternate cable when a link failure condition is detected on the cable currently in use. The circuit provides automatic cable redundancy, with any interruption in communication being limited only to the time required to determine link failure and to switch over to the alternate cable path.

### FIELD OF THE INVENTION

This invention relates to network communications, and, more particularly, to a method and apparatus for cable redundancy in network data links.

### BACKGROUND OF THE INVENTION

In today's business world, reliable and efficient access to information has become an important asset in the quest to achieve a competitive advantage. File cabinets and mountains of papers have given way to computers that store and manage information electronically. Coworkers thousands of miles apart can share information instantaneously, just as hundreds of workers in a single location can simultaneously review research data maintained online.

In addition, systems can be controlled and monitored from almost anywhere in the world with the proper connection.

Computer networking technologies are the glue that binds these elements together. The public Internet allows businesses around the world to share information with each other and their customers. The global computer network known as the World Wide Web provides services that let consumers buy books, clothes, and even cars online, or auction those same items off when no longer wanted.

Networking allows one computer to send information to and receive information from another. Certainly the Internet is the most conspicuous example of computer networking, linking millions of computers around the world, but smaller networks play a roll in information access on a daily basis. Many public libraries have replaced their card catalogs with computer terminals that allow patrons to search for books far more quickly and easily. Airports have numerous screens displaying information regarding arriving and departing flights. Many retail stores feature specialized computers that handle point-of-sale transactions. In each of these cases, networking allows many different devices in multiple locations to access a shared repository of data.

Many industrial control systems and other mission-critical control applications require redundancy of data cable transmission paths to allow for the contingency of a data cable in use being accidentally cut or damaged without losing communications. A redundant cable system allows control and communication to continue despite a failure in a data cable.

Some attempts to create a useful and cost effective cable redundancy have been made, including U.S. Pat. No. 5,485,465 to Liu et al. Liu et al. teaches a communication link redundancy system. The Liu et al. patent teaches a redundancy system that starts a timer running upon reception of a packet on the secondary link. According to the Liu et al. disclosure, if a corresponding packet is not received on the primary link within a predetermined period of time an error signal is generated and a counter is incremented. When the count reaches a predetermined value_communications are switched over to the secondary link. While such a system may sometimes indicate a fault in the cable, it may also simply be a problem with the signal packets or some other problem. Liu et al. does not truly determine the physical viability of the communications link.

U.S. Pat. No. 6,173,411 to Hirst et al. also concerns network link redundancy, but the disclosure of Hirst et al. teaches a very complex, obtrusive, and expensive system. The Hirst redundancy system uses a redundancy interface unit similar with one local node connection and primary and secondary link connections. However, the Hirst et al. system teaches a separate managed network switch unit placed between the primary and secondary connections and the main network. The redundancy interface periodically communicates with the target device located somewhere in the network by sending “ping” messages over the primary link connection. If the ping is successful, the primary connection will be used for all traffic and both the primary and secondary switches learn the correct routing for traffic to the local node is through the primary connection. If the ping fails, a ping will be issued over the secondary connection. If this secondary ping is successful, then the redundancy interface unit switches over to the secondary connection for all traffic and the primary and secondary switch units learn the new routing automatically. However, network switches are costly and the Hirst et al. system requires active management of the redundancy interface unit (referred to as the “link manager” in the Hirst et al. disclosure). Further, switchover time in the case of link failure according to the teachings of Hirst et al. may be significant when the distance between network nodes (which the “ping” must travel) is long. Further, the hardware of the redundancy unit according to Hirst et al. is extensive and expensive.

In a different vein, U.S. Pat. No. 6,202,169 to Razzaghe-Ashrafi et al. refers to logical redundancy, but not to physical cable redundancy. According to Razzaghe-Ashrafi et al., there are two redundant computer systems residing on the same network and only one of the two machines is actively communicating with other nodes on the network. If one of the two machines is disabled, the redundant machine transmits an unsolicited ARP reply with the same IP address as the alternate machine, thus forcing all other nodes on the network to re-map their IP address resolution tables for that IP address from the MAC address of the primary machine to the MAC address of the redundant machine. Again, however, Razzaghe-Ashrafi et al. does not a physical cable redundancy system.

Additionally, Shore Microsystems of Long Branch, NJ offers a gigabit link protector model SM-2508. Shore's product is designed for a large server installation and requires a 19″ rack for mounting in a computer room. It is adapted for connection to a server. The Shore product is large and complex, with a multi-processor computer, dedicated firmware, and multi-ASIC or FPGA (field-programmable gate array), with multiple banks of memory. The Shore product may not simply be added as an afterthought, it is an upfront constraint. The Shore product requires some programming and configuration, adding to the expense and complexity of a redundancy system.

The present invention attempts to eliminate, or at least reduce the effects of, one or more of the problems stated above.

### SUMMARY OF THE INVENTION

The present invention meets the above-described needs and others. Specifically, the present invention provides an autonomous circuit enabling the routing of data at a local network port to either a primary or secondary network cable connected to primary and secondary network ports. The circuit includes: a first device, such as a PHY, for monitoring link status of the primary network cable; an application-specific logic device, such as a complex programmable logic device (CPLD), for monitoring the link status reported by the first PHY; and a switchover device, such as a relay, for routing data to one or the other of the primary or secondary network cables.

The circuit may further include a network repeater device, such as a network hub, for re-transmitting data from a local network port, the hub having a primary and secondary port for both receiving incoming data and sending outgoing data. The circuit may include a second PHY for monitoring the link status of the secondary network cable and secondary node. The CPLD may monitor the link status reported by the first and second PHYs. The CPLD may cause a simple switching device, such as a relay, to change the route of the data from the primary cable to the secondary cable if the first PHY reports a fault in the primary network cable or primary port, and the second PHY reports no fault in the secondary network cable or the secondary port. Further, the CPLD may cause the relay to change the route of the data from the secondary cable to back to the primary cable if the second PHY reports a fault in the secondary network cable or the secondary port, and the first PHY reports no fault in the primary network cable or the primary port.

According to one aspect of the invention, the first and second PHY's may be replaced by one or more programmable logic devices or ASICs.

According to one aspect of the invention, the only purpose of the first and second PHYs may be monitoring the link status of the primary and secondary network cables, their associated ports, and reporting the status using a PHY link status output associated with each of the first and second PHYs. According to this aspect of the invention, neither the first nor second PHY is used as an interface between a physical cable medium and a network MAC device, which is their normal and intended application in network circuits.

According to one aspect of the invention, the first PHY may be replaced by a programmable logic device or an ASIC.

According to one aspect of the invention, the only purpose of the first PHY is monitoring the link status of the primary or secondary network cables and their associated nodes, and reporting the status using a PHY link status output associated with the first PHY. According to this aspect of the invention, the first PHY is not used as an interface between a physical cable medium and a network MAC device, which is their normal and intended application in network circuits.

According to one aspect of the invention, the CPLD may cause the switch to route the data to the secondary network cable when the first PHY indicates a fault in the primary network cable or the primary node.

According to one aspect of the invention, the first PHY may switch from monitoring the primary network cable and primary node to monitoring the secondary network cable and secondary node when the switch routes the data to the secondary network cable. In addition, the CPLD may switch the signals back to the primary network cable when the first PHY indicates a fault in the secondary network cable or secondary node.

According to one aspect of the invention, the primary and secondary network cables may include an Ethernet network, for example a 10/100 Base-TX Ethernet network.

According to one aspect of the invention, the primary and secondary network cables may generally include one of any number of modern network media standards, for example a fiber distributed data interface (FDDI), a token ring network, or an asynchronous transfer mode (ATM). The FDDI may be a fiber optic 100 base-FX.

According to one aspect of the invention, the primary and secondary network cables connect to nodes, and not to a server, but could generally be used for connection to any type of network-connected device.

According to one aspect of the invention, the circuit may be packaged in a housing of dimensions no greater than five inches high, by ten and one-half inches deep, by eighteen inches wide.

According to one aspect of the invention, a single instance of the circuit may service only a single network link, however multiple instances of the circuit could be housed in an enclosure to provide physical cable redundancy to any number of different network links.

According to one aspect of the invention, the circuit may include hardware only. That is, the circuit would normally include no user-configurable parameters and no embedded software, however any number of variations and feature enhancements to provide greater functionality for the user could be added to the circuit, including user-configurable parameters and embedded software, for example.

According to one aspect of the invention, there is disclosed a method of creating a cable redundancy including: monitoring a primary network cable with a first PHY and switching data traveling along the primary network cable to a secondary network cable when a fault is detected in the primary network cable, where a link status output on the first PHY indicates the status of the primary network cable.

According to one aspect of the invention, the switching of data traveling along the primary network cable to the secondary network cable may be accomplished without any active management of monitoring or switching apparatus, and with no programming or firmware, however any number of variations and feature enhancements to provide greater functionality for the user could be added to the circuit, including user-configurable parameters and embedded software, for example.

According to one aspect of the invention, the method may include monitoring the secondary network cable with a second PHY, where a link status output on the second PHY indicates the status of the secondary network cable.

According to one aspect of the invention, the first PHY switches to monitor the secondary network cable and no longer monitors the primary network cable when the data is switched to travel along the secondary network cable, wherein the first PHY link status output indicates the status of the secondary network cable. That is, according to one aspect of the invention the first PHY monitors whichever network cable is currently in use. The method may further include switching the data traveling along the secondary network cable back to the primary network cable when a fault is detected by the first PHY in the secondary network cable.

According to one aspect of the invention, there is disclosed a method of administering a redundant cable system comprising: monitoring primary and secondary network cables with first and second PHY's, respectively; and switching a data stream route from the primary network cable to the secondary network cable when the first PHY indicates a fault in the primary network cable and the second PHY indicates no faults in the secondary network cable. The faults in the primary and secondary network cables may be indicated solely by link status outputs on each of the first and second PHYs.

According to one aspect of the invention, the switching of the data stream along the primary network cable to the secondary network cable may be accomplished without any active management of monitoring apparatus, however any number of variations and feature enhancements to provide greater functionality for the user could be added to the circuit, including user-configurable parameters and embedded software, for example.

According to one aspect of the invention, the monitoring of and switching from the primary network cable are accomplished with no programming and no firmware, however any number of variations and feature enhancements to provide greater functionality for the user could be added to the circuit, including user-configurable parameters and embedded software, for example.

According to one aspect of the invention, the method may further include switching the data stream route from the secondary network cable to the primary network cable when the second PHY indicates a fault in the secondary network cable and the first PHY indicates no faults in the primary network cable.

According to one aspect of the invention, the circuit may provide external electrical indications of the primary and secondary network port status. These indications may be used to notify other equipment of the network port and cable status.

According to one aspect of the invention, the circuit may be integrated into products that connect directly to primary and secondary Ethernet network cables.

Additional advantages and novel features of the invention will be set forth in the description which follows or may be learned by those skilled in the art through reading these materials or practicing the invention. The advantages of the invention may be achieved through the means recited in the attached claims.

### BRIEF DESCRIPTION OF THE DRAWINGS

The accompanying drawings illustrate preferred embodiments of the present invention and are a part of the specification. Together with the following description, the drawings demonstrate and explain the principles of the present invention.

FIG. 1 is a cable redundancy topology according to one embodiment of the present invention.

FIG. 2 is a circuit diagram for the embodiment of FIG. 1

FIG. 3 is one of many possible circuit board layouts compatible with the embodiment of FIG. 1.

FIG. 4 is a mechanical drawing of one of many possible form factors that the present invention might take in the three principle views according to one embodiment of the present invention.

FIG. 5 is a node redundancy topology according to one embodiment of the present invention.

FIG. 6 is a circuit diagram for the embodiment of FIG. 5

FIG. 7 is one of many possible circuit board layouts compatible with the embodiment of FIG. 5.

Throughout the drawings, identical elements are designated by identical reference numbers.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

DETAILED DESCRIPTION OF THE PREFERRED EMBODIMENTS

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, that will vary from one implementation to another. Moreover, it will be appreciated that such a development effort might be complex and time-consuming, but would nevertheless be a routine undertaking for those of ordinary skill in the art having the benefit of this disclosure.

Description of Terms

The following terms and their associated definitions are used throughout the description and claims and are included here for convenient reference.

10/100 Base-TX—An Ethernet network standard defined in the IEEE 802.3 series of standards. “10/100” denotes a Base-T type network where the devices are capable of negotiating speeds of data links to be either 10 Mbits/sec or 100 Mbits/sec and either half duplex or full duplex, depending on device capabilities.

10 Base-T—An Ethernet network standard defined in the IEEE 802.3 series of standards. A Base-T type network where the data links operate at 10 Mbits/sec.

100 Base-TX—An Ethernet network standard defined in the IEEE 802.3 series of standards. A Base-T type network where the data links operate at 100 Mbits/sec.

100 Base-FX—An Ethernet network standard defined in the IEEE 802.3 series of standards. A Base-FX type network where the data links operate at 100 Mbits/sec.

4PDT—Four Pole Double-Throw. An electromechanical switching device, such as a toggle switch or relay, capable of switching 4 lines to one or another set of 4 lines. A 4PDT relay can be made from two DPDT relays.

ARP—Address Resolution Protocol. A method for relating logical network addresses (IP addresses) and physical network node addresses (MAC addresses).

ASIC—Application Specific Integrated Circuit. A custom-designed logic circuit chip intended to perform a specific function.

Base-FX —A physical implementation of the IEEE 802.3 standards that uses fiber optic cable as a medium.

Base-T—A physical implementation of the IEEE 802.3 standards that uses four twisted-pair copper cable (category 3,4, or 5 cable) as a medium with RJ-45 connectors.

Category 3, 4, or 5—Four twisted-pair copper cable that meets the performance requirements of the IEEE 802.3 standards.

CPLD—Complex Programmable Logic Device. An array of logic cells that retain configuration through power cycles. The array is configurable to represent different digital logic circuits, and can be programmed using schematics or various Hardware Design Languages (HDL).

CPU—Central Processing Unit. A computing device containing a microprocessor or microcontroller and memory.

CRC—Cyclic Redundancy Check. A method for performing error checking on a stream of received data.

DC—Direct Current. Voltage that does not change over time.

DIN rail—A standard equipment rail to which various equipment are easily mounted. Commonly used in industrial equipment.

DPDT—Double-Pole Double-Throw. An electromechanical switching device, such as a toggle switch or relay, capable of switching 2 lines to one or another set of 2 lines.

Ethernet—A general term for a series of network standards defined by the IEEE 802.n series of standards.

Hub—Also referred to as a repeater. A network device with three or more ports that will re-transmit incoming data from any one of the ports onto all of the other ports. If more than one port attempts to transmit data to the hub at the same time, a logical collision occurs; devices on all ports of the hub will detect that the collision occurred, and will back off and attempt to re-transmit after a random time interval.

IEEE—Institute of Electrical and Electronics Engineers. A society responsible for standardizing electrical and electronics technologies and for generally promoting the field of electrical and electronic design.

IP Address—Internet Protocol Address. A logical address for a network device.

LED—Light-Emitting Diode. A semiconductor device that glows brightly in a specific color when current is passed through it.

MAC Address—Media Access Controller Address. A unique physical address that is assigned to all Ethernet devices.

Network Switch—Similar to a hub or repeater, but treats each port as a separate collision domain. Over time the network switch “learns” the addresses of devices that reside on its various ports and stores these addresses in a table in local memory. When a device on one of the switch ports begins a transmission the switch will check the destination address in the incoming transmission and forward it on only to the appropriate port. If the destination address does not reside on any of the switch's ports, it will not forward the transmission on any further. Network switches may be managed or unmanaged; the term “managed” refers to the presence of a local processor that controls and/or monitors operation of the switch.

Ping—A test message that can be sent from one network node to another network node to test the presence of the second node and the continuity of the network link.

PLC—Programmable Logic Controller. A ruggedized industrial system of specialized I/O modules that can be configured to control or monitor a wide variety of machinery and electrical systems.

PHY—PHYsical layer transceiver. A device that translates from purely logical network messaging to the standard for the physical media being used. For instance, an Ethernet 10/100 Base-TX network link would either have a different PHY device than a 100 Base-FX link or would have capabilities for both incorporated into its design.

SMD—Surface-Mount Device. A board-mounted electronic part whose metal connections to traces on the board reside only on the top or bottom surface of the board. Through-hole parts are a different type whose metal connections to traces on the board consist of pins ≦≈0.2″ that extend from one surface of the board through a metal-plated hole in the board and out the opposite side of the board.

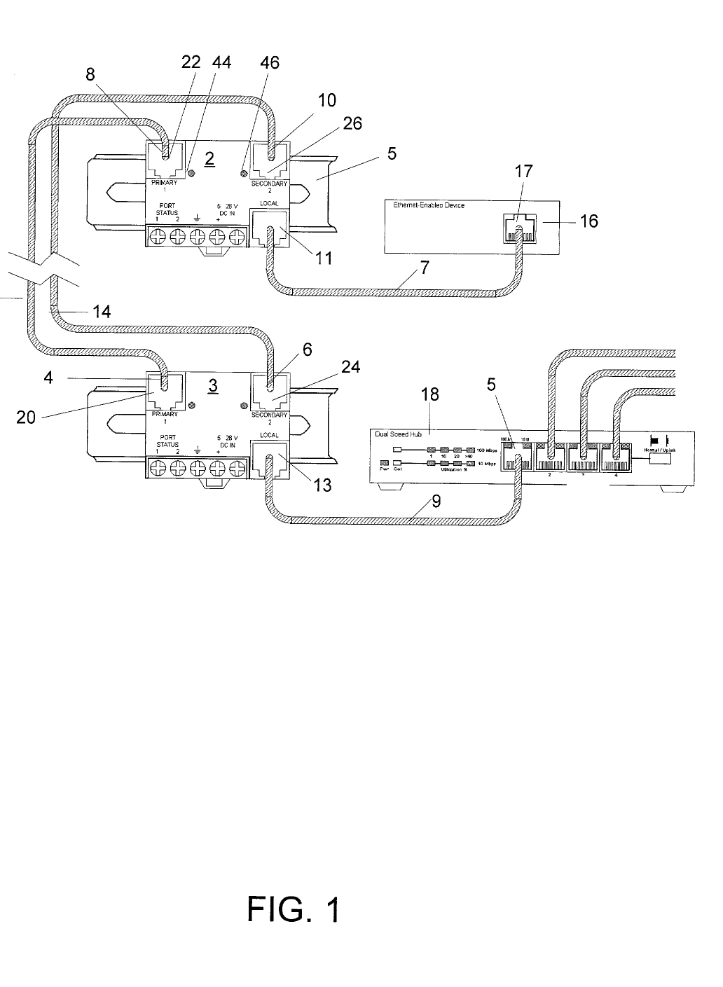

Turning now to the figures, and in particular to FIG. 1, one embodiment according to the present invention is disclosed. FIG. 1 is a diagram of a first basic system topology for implementing a cable redundancy. In the embodiment of FIG. 1, a monitoring/switching device (2 & 3) according to the present invention is installed at each end (4 & 6) and (8 & 10) of primary and secondary network cables, for example 10/100 Base-TX Ethernet cables (12 & 14). It will be understood by those of skill in the art with the benefit of this disclosure, however, that primary and secondary network cables may include other data and/or communications networks including, but not limited to 10 BaseT, 100 Base-TX, a fiber distributed data interface (FDDI) including 100 Base-FX, a token ring network, or an asynchronous transfer mode (ATM). First end (4) of primary network cable (12) connects to the primary port (20) of monitoring/switching device (3), and second end (8) connects to the primary port (22) of monitoring/switching device (2). Similarly, first end (6) of secondary network cable (14) connects to the secondary port (24) of monitoring/switching device (3), and second end (10) connects to the secondary port (26) of monitoring/switching device (2).

As shown in FIG. 1, monitoring/switching devices (2 & 3) monitor the line status of each of primary and secondary network cables (12 & 14) and the associated ports (20-26). Monitoring/switching devices (2 & 3) may switch the stream of data available normally through primary network cable (12) to secondary network cable (14) if a fault is detected in primary network cable (12) or ports (20 & 22). Similarly, if the stream of data has been switched to secondary network cable (14) and monitoring/switching devices (2& 3) detect a fault in secondary network cable (14) or ports (24 & 26), the data stream may be routed once again to primary network cable (12).

In the embodiment shown in FIG. 1, monitoring/switching device (2) is located local to an Ethernet-enabled device (16) and connected via a short local cable (7) to local network port (11) of the monitoring/switching device (2). The Ethernet-enabled device (16) may be a personal computer, a control module, or any other Ethernet-enabled device. Monitoring/switching device (3) is located local to a hub, for example dual speed hub (18), which may be sending and receiving data to or from Ethernet-enabled device (16). The hub (18) is connected via a short local cable (9) to local port (13) of the monitoring/switching device (3). Monitoring/switching devices (2) and (3) are identical in the embodiment shown and may include a metal DIN mounting rail (5).

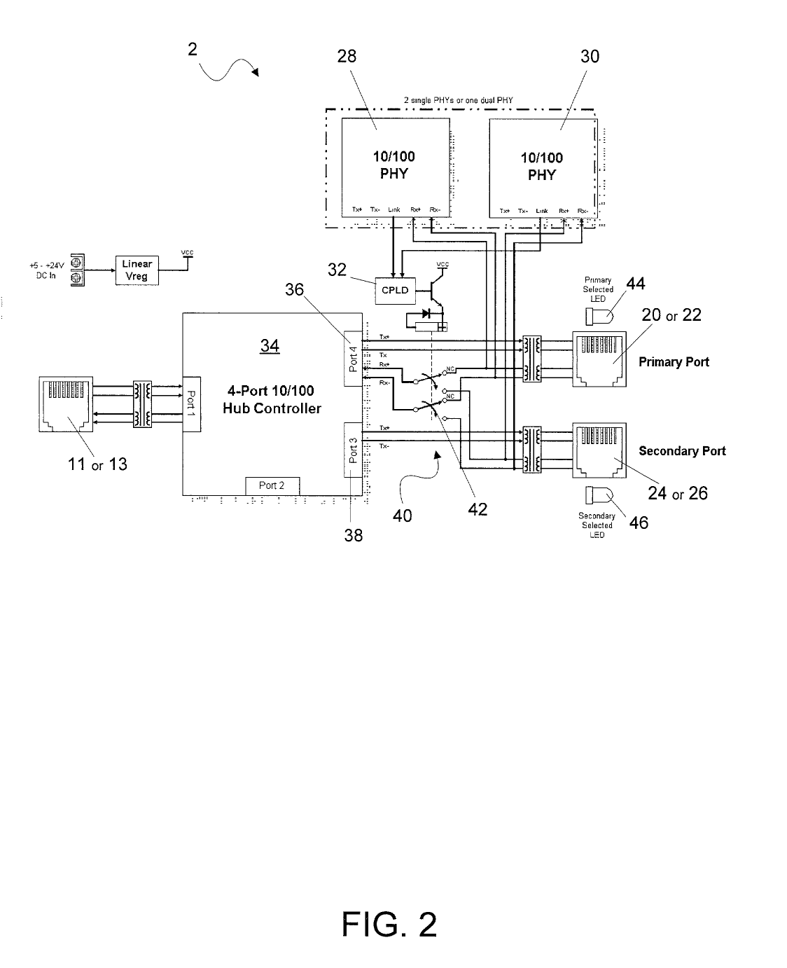

The operation of monitoring/switching device (2) may be described in conjunction with reference to one embodiment of a basic circuit diagram for monitoring/switching device (2) as shown in FIG. 2. Monitoring/switching device (2) may include two monitoring devices, for example PHYs (28 & 30). The two PHYs (28 & 30) may include two single PHYs or one dual PHY. First PHY (28) may be used to monitor the link status of primary network cable (12) and its associated ports (20 & 22). According to the embodiment of FIG. 2, first PHY (28) and second PHY (30) are not used according to the typical application of PHYs as an interface between physical cable medium and an Ethernet MAC device. Rather, first PHY (28) has as its sole purpose in the present embodiment to monitor link status of the primary network cable (12) and its associated ports (20 & 22), and report the link status to a logic device, for example a CPLD (32). Likewise, second PHY (30) has as its sole purpose in the present embodiment to monitor link status of the secondary network cable (14) and its associated ports (24 & 26), and report the link status to the CPLD (32). PHYs (28 & 30) report link status of their respective network cables using normal LED status outputs (44 & 46) of each PHY.

In an alternative embodiment, PHYs (28 & 30) may be replaced with a programmable logic device or an ASIC, however, PHYs (28 & 30) are more simple to use, require no programming, and are much less expensive than ASICs or programmable logic devices.

With monitoring/switching devices (2 & 3) on each end of the network cables and two PHYs (28 & 30), both primary network cable (12) and secondary network cable (14) may be monitored at the same time. A repeater device, for example a 4-port 10/100 hub controller (34) shown in FIG. 2, may retransmit data communications onto both of its outgoing ports (36 & 38) and subsequently through device ports (20 or 22 & 24 or 26) and out onto both the primary and secondary network cables (12 & 14).

CPLD (32), which monitors the link status reported via the link status outputs of the PHYs (28 & 30), may then monitor the “health” or operability of both primary network cable (12) and secondary network cable (14). If the network cable currently in use (normally primary network cable (12)—but not necessarily so) is indicated to be faulty by its corresponding PHY for longer than a predetermined amount of time, then CPLD (32) will issue a signal to a switching device (40), in this case a relay, to switch data transmission from the local port (11) over to the alternative network cable (normally secondary cable (14)). Switching device (40) will then execute the switch command as indicated by arrows (42).

However, according to the circuit embodied in FIG. 2 employing 4-port 10/100 hub controller (34), if the alternate network cable (and/or ports) is also indicated to be faulty by its corresponding PHY, then the switchover does not necessarily have to take place. CPLD (32) may not initiate a switchover action unless at least one of the two network cables (12 & 14) and their associated ports is reported to be “healthy” by the PHYs (28 & 30); the decision of whether to switchover or not in the case when neither network cable (12 & 14) is “healthy” is left solely to the discretion of the product designer. Choosing not to switchover in the case when neither network cable (12 & 14) is “healthy” is the recommended option since it prevents switchover oscillation between the two ports.

Therefore, according to the embodiments shown in FIGS. 1 and 2, a circuit (2) may advantageously be constructed of hardware alone without the need for any firmware, programming, or active monitoring to provide a redundant network that will switch transmissions from a faulty network cable to a working secondary cable, or viceversa. In most embodiments, this circuit is used between two nodes (for example 5 & 17) and not connected to a server, and it may be inserted as an afterthought to a network. However, the circuit could be used in any application where two network nodes of any type require cable redundancy over a direct cable connection between the two nodes.

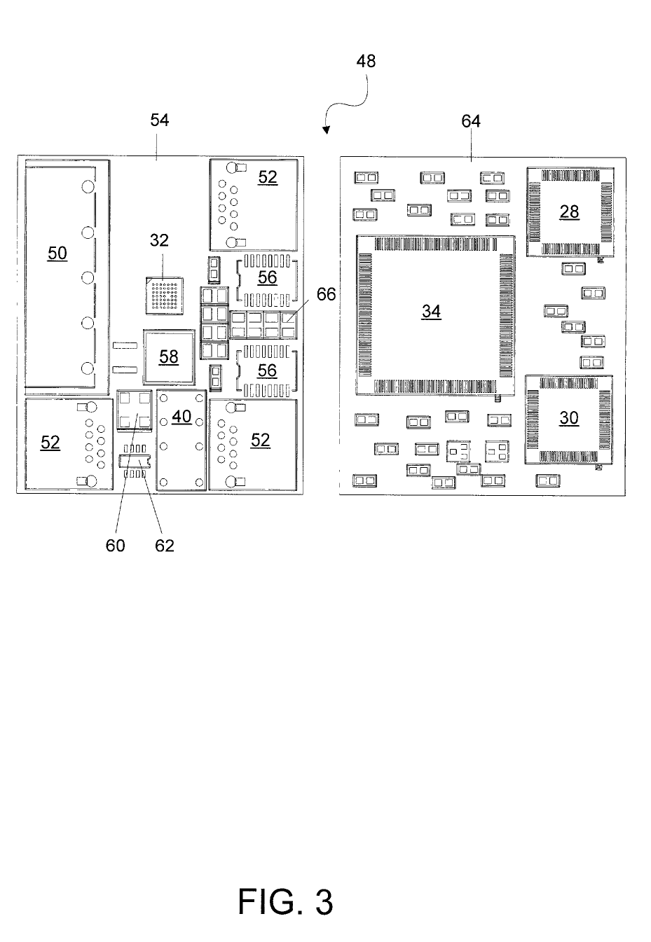

Turning next to FIG. 3, an exemplary circuit board layout (48) according to the implementation described in FIGS. 1 and 2 is shown. Circuit board layout (48) may include top side (54) and bottom side (64). Top side (54) may include one or more terminal strips (50) available from, for example Reed Devices. A model 6PCV-05-000 may be used. In the embodiment shown, three terminal strips are used. The circuit board may also include a shielded RJ-45 connector (52), available from RIA Electronics, for example model number AJS07A8813. Three RJ-45 connectors (52) are employed according to the present embodiment and located at three corners of the circuit board (54).

Circuit board layout (48) also may include magnetics (56), for example between two of the RJ-45 connectors (52). Magnetics (56) are available from Halo, for example Halo TG110-505N2 may be used. In the embodiment shown three magnetics (56) are used.

CPLD (32) is shown approximately centrally located on top side (54) of FIG. 3. CPLD (32) is available from Xilinx, for example model number XC9536 CSP. A voltage regulator (58) is available from SGS-Thompson, for example a model SGS-T L 7805CD2T is shown adjacent CPLD (32).

Also shown on circuit board layout (48) is switching device (40). Switching device (40) is shown as a DPDT relay, with a 20 mA coil. Such a switching device is available, for example, from Omron as model number G6K-2G-Y DC5. In the embodiment shown, two switching devices (40) are used. Various resistors and capacitors are also shown adjacent to switch (40).

An oscillator, for example 25 MHz oscillator (60) available from Raltron as model number C04910-20.0000-EXT-T, is included on circuit board (54).

A reset circuit (62) may be included to reset the circuit. Reset circuit (62) is available from Maxim, for example a MAX709 reset circuit may be used.

PHY's (28 & 30), as well as 4-port 10/100 hub controller (34) are shown adjacent one another on bottom side (64).

Finally one or more and preferably eight 0.01 uF 1 kV capacitors, available from AVX as model 1210AC103KAT1a, are shown along with a diode available from, for example, Zetex as model BAT54C and a NPN 100 mA min. transistor available from, for example, Motorola as model MMBT2222AT1 at item (66).

It will be understood by those of skill in the art with the benefit of this disclosure that the circuit board layout and components are but one example of implementing the invention as described above and below.

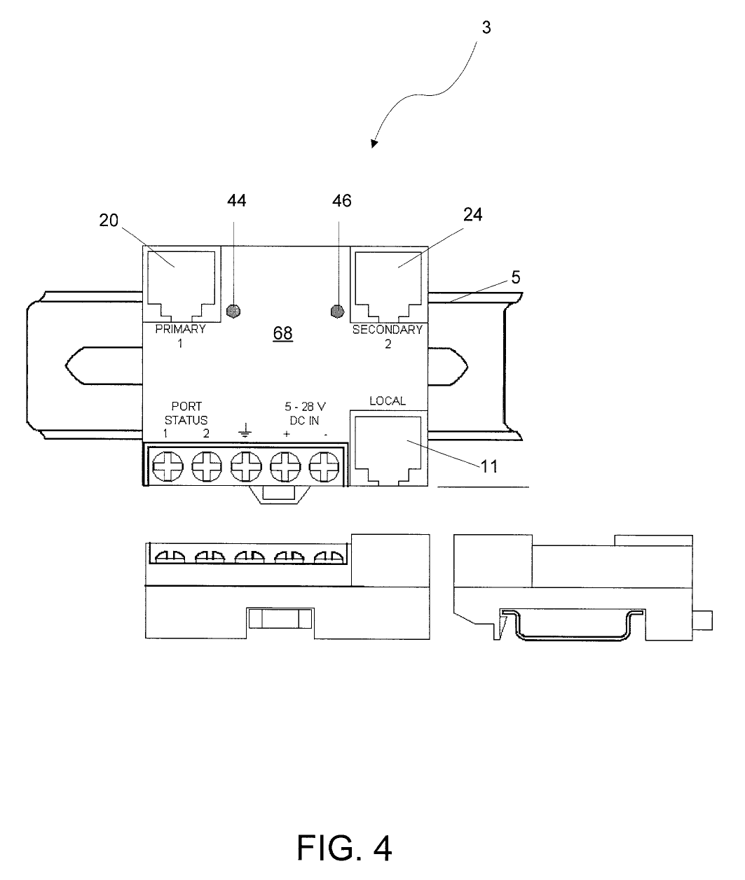

Turning next to FIG. 4, a housing (68) for circuit board layout (48) according to one embodiment of the present invention is shown. FIG. 4 shows each of the principle views of housing (68). The dimensions of housing (68) do not typically exceed five inches high, by ten and one-half inches deep, by eighteen inches wide. Preferably the dimensions do not exceed one and one-half inches high, by three inches deep, by five inches wide. Most preferably, the dimensions are about one inch high, by two and three tenths inches deep, by three and one-half inches wide.

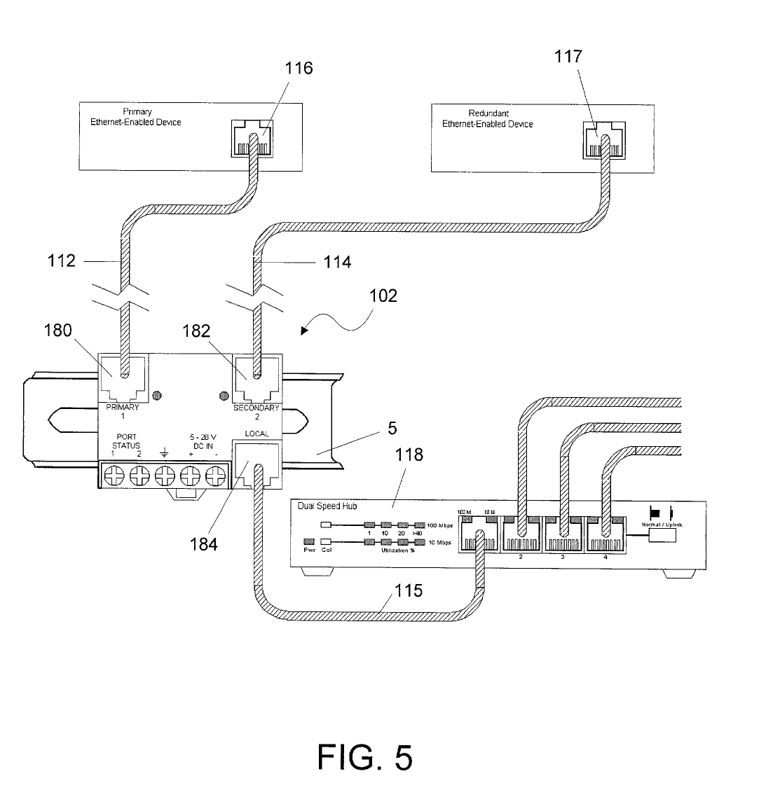

Referring next to FIG. 5, another embodiment according to one aspect of the present invention is shown. FIG. 5 shows a node redundancy topology. According to this embodiment, only one monitoring/switching device (102) is included. In the embodiment shown, monitoring/switching device (102) is located local to a data source or hub, for example dual speed hub (118), but this is not necessarily so. The data source is connected via a short local cable (115) to local network port (184) of the monitoring/switching device (102). The monitoring/switching device (102) is connected to an independent network node (116) via a primary network cable (112) connected to primary network port (180), and also to a redundant network node (117) via a secondary network cable (114) connected to the secondary network port (182). According to the embodiment of FIG. 5, monitoring/switching device (102) switches data communications from the primary network cable (112) to the secondary network cable (114) in the event that primary network cable (112) or node (116) is determined to be faulty, or vice-versa.

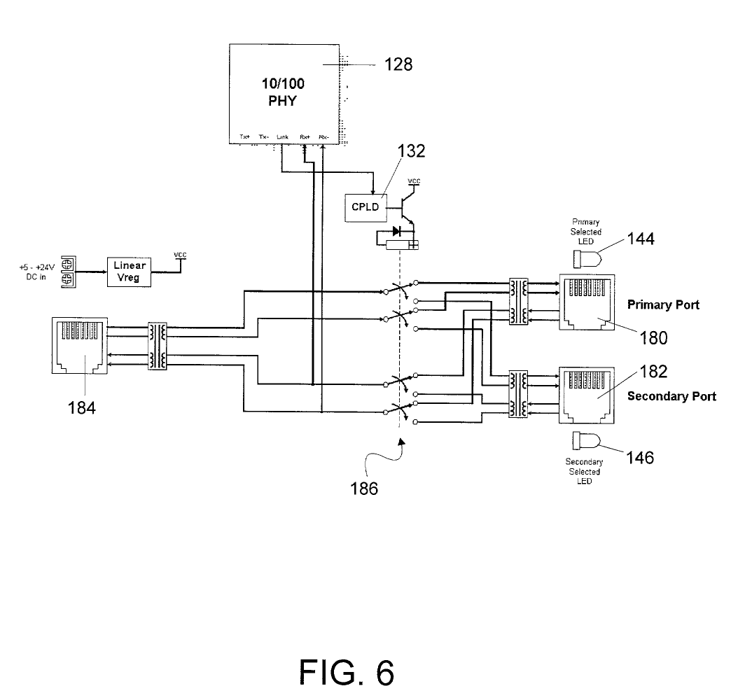

The operation of monitoring/switching device (102) may be described in conjunction with reference to one embodiment of a basic circuit diagram for monitoring/switching device (102) as shown in FIG. 6. Monitoring/switching device (102) may include only one PHY (128). The PHY (128) may be used to monitor the link status of primary network cable (112) and its associated node (116). According to the embodiment of FIG. 6, the PHY (128) is not used according to the typical application of a PHY as an interface between physical cable medium and a network MAC device. Rather, the PHY (128) has as its purpose in the present embodiment to monitor link status of the currently active network cable (112 or 114) and its associated node (116 or 117), and report the link status to a CPLD (132). PHY (128) reports link status of the currently active network cable (112 or 114112) and associated node (116) using normal LED status output.

In an alternative embodiment, PHY (128) may be replaced with a programmable logic device or an ASIC, however, PHY (128) is simpler to use, requires no programming, and is much less expensive than ASICs or programmable logic devices.

With only a single monitoring/switching device (102), only one of primary network cable (112) or secondary network cable (114) may be monitored at any given time. In addition, there is no hub device according to the embodiment shown in FIG. 6. Therefore, only the network cable currently in use can be monitored by PHY (128). If the cable and/or node currently in use is indicated to be faulty by PHY (128), then CPLD (132) will issue a signal to switchover data transmissions to the alternate cable and node. If the alternate cable and/or node is also faulty, the switchover back to the primary cable and node will still occur, as the CPLD has no knowledge of the status of the cable, node, and port (either 180 or 182) not currently in use. After a switch has occurred, PHY (128) now monitors the cable, and node in use, and no longer monitors the cable that has become the alternate. Therefore, in some embodiments of FIG. 6 a time delay may be inserted into CPLD (132) algorithms before monitoring/switching device (102) is permitted to cause a switch after just having switched, else rapid oscillation between ports could occur.

The switchover action according to the embodiment of FIG. 6 includes routing one or the other of the primary or secondary ports (180 or 182) receive lines to local node port (184) as shown by arrows (186). The switchover to route one or the other port's lines to local node (184) may be done using a 4PDT relay controlled by a switchover output signal from CPLD (132). Transmit lines going out from the local node port (184) are routed to both primary and secondary ports (180 & 182) at all times; only the receive lines from the primary and secondary ports (180 or 182) are switched to local node port (184).

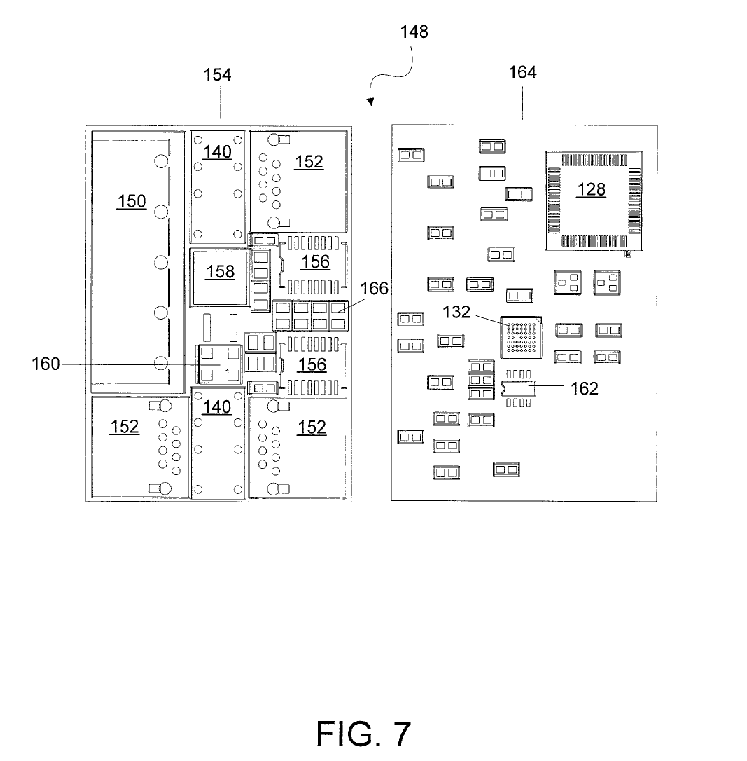

Turning next to FIG. 7, an exemplary circuit board layout (148) according to the implementation described in FIGS. 5 and 6 is shown. Circuit board layout (148) may include one or more terminal strips (150) available from, for example Reed Devices on top side (154) of the circuit board. A model 6PCV-05-000 may be used. In the embodiment shown, three terminal strips are used. The circuit board may also include a shielded RJ-45 connector (152), available from RIA Electronics, for example model number AJS07A8813. Three RJ-45 connectors (152) are employed according to the present embodiment and located at three corners of the top side (154).

Circuit board layout (148) also may include magnetics (156) between two of the RJ-45 connectors (152). Magnetics (156) are available from Halo, for example Halo TG10-505N2 may be used. In the embodiment shown three magnetics (156) are used.

CPLD (132) is shown approximately centrally located on bottom side (164) of the circuit board shown in FIG. 7. CPLD (132) is available from Xilinx, for example model number XC9536 CSP. A voltage regulator (158) is available from SGSThompson, for example a model SGS-T L 7805CD2T is shown adjacent in a generally central location of top side (154).

Also shown on circuit board layout (148) is switch (140). Switch (140) is shown as a 4PDT relay created from two DPDT relays. Such a switch is available, for example, from Omron. Various resistors and capacitors are also shown adjacent to switch (140).

An oscillator, for example 25 MHz oscillator (160) available from Raltron as model number CO4910-20.0000-EXT-T is included on circuit board (154).

A reset circuit (162) may be included to reset the circuit. Reset circuit (162) is available from Maxim, for example a MAX709 reset circuit may be used.

PHY (128) is also shown on bottom side (164) of the circuit board.

Finally one or more and preferably eight 0.01 uF 1 kV capacitors, available from AVX as model 1210AC103KAT1a, are shown along with a diode available from, for example, Zetex as model BAT54C and a NPN 100 mA min. transistor available from, for example, Motorola as model MMBT2222AT1 at item (166).

It will be appreciated by those of skill in the art with the benefit of this disclosure that the circuits described above do not require the use of any network switches, which could add to the expense of the monitor/switches.

The preferred embodiments were chosen and described in order to best explain the principles of the invention and its practical application. The preceding description is intended to enable others skilled in the art to best utilize the invention in various embodiments and with various modifications as are suited to the particular use contemplated. It is intended that the scope of the invention be defined by the following claims.

What is claimed is:

1. An autonomous circuit enabling the routing of data to a primary or secondary network cable connected to primary and secondary nodes comprising:
a first monitoring device for reporting link status of the primary network cable;
a logic device for monitoring the link status reported by the first monitoring device; and
a switching device for routing the data to one or the other of the primary or secondary network cables.

2. The circuit of claim 1, further comprising a repeater device for re-transmitting data from a local network port, the repeater device having at least two ports from which the repeater device can transmit outgoing data and at least one port, which can be used for receiving incoming data.

3. The circuit of claim 2, further comprising a second monitoring device for reporting the link status of the secondary network cable and secondary node.

4. The circuit of claim 3, wherein the second monitoring device comprises a PHY.

5. The circuit of claim 3, wherein the logic device monitors the link status reported by the second monitoring device.

6. The circuit of claim 5, wherein the logic device causes the switching device to change the route of the data from the primary cable to the secondary cable if the first monitoring device reports a fault in the primary network cable or primary port, and the second monitoring device reports no fault in the secondary network cable or the secondary port.

7. The circuit of claim 6, wherein the logic device causes the switching device to change the route of the data from the secondary cable to the primary cable if the second monitoring device reports a fault in the secondary network cable or the secondary port, and the first monitoring device reports no fault in the primary network cable or the primary port.

8. The circuit of claim 3, wherein the first and second monitoring devices are replaced by one or more programmable logic devices or ASICs.

9. The circuit of claim 3, wherein the only purpose of the first and second monitoring devices is monitoring the link status of the primary and secondary network cables and their associated ports, and reporting the status using a link status output associated with each of the first and second monitoring devices.

10. The circuit of claim 9, wherein neither the first nor second monitoring device is used as an interface between a physical cable medium and a network MAC device.

11. The circuit of claim 1, wherein the first monitoring device is replaced by a programmable logic device or an ASIC.

12. The circuit of claim 1, wherein the only purpose of the first monitoring device is monitoring the link status of the primary or secondary network cables and their associated nodes, and reporting the status using a link status output associated with the first monitoring device.

13. The circuit of claim 12, wherein the first monitoring device is not used as an interface between a physical cable medium and a network MAC device.

14. The circuit of claim 1, wherein the logic device causes the switching device to route the data to the secondary network cable when the first monitoring device indicates a fault in the primary network cable or the primary node.

15. The circuit of claim 14, wherein the first monitoring device is disconnected from monitoring the primary network cable and primary node and connected to monitoring the secondary network cable and secondary node when the switching device routes the data to the secondary network cable.

16. The circuit of claim 15, wherein the logic device routes the signals back to the primary network cable when the first monitoring device indicates a fault in the secondary network cable or secondary node.

17. The circuit of claim 1, wherein the primary and secondary network cables comprise an Ethernet network.

18. The circuit of claim 17, wherein the Ethernet network is a 10/100 Base-TX Ethernet network.

19. The circuit of claim 1, wherein the primary and secondary network cables comprise one of: a fiber distributed data interface (FDDI), a token ring network, or an asynchronous transfer mode (ATM).

20. The circuit of claim 19, wherein the FDDI is a fiber optic 100 base-FX.

21. The circuit of claim 1, wherein the primary and secondary network cables connect to nodes, and not to a server.

22. The circuit of claim 1, wherein the circuit is packaged in a housing of dimensions no greater than five inches high, by ten and one-half inches deep, by eighteen inches wide.

23. The circuit of claim 1, wherein the circuit may service only a single Ethernet link.

24. The circuit of claim 1, wherein the circuit comprises hardware only.

25. The circuit of claim 24, wherein the circuit comprises no user configurable parameters and no firmware.

26. The circuit of claim 1, wherein the circuit is integrated within another Ethernet device to provide automatic redundant network cable operation, or operation with redundant network devices.

27. The circuit of claim 1, wherein the circuit provides electrical outputs to indicate the primary and secondary network cable status to other equipment.

28. The circuit of claim 1, wherein the monitoring device comprises a PHY.

29. The circuit of claim 1, wherein the logic device comprises a CPLD.

30. A method of creating a cable redundancy comprising:
monitoring a primary network cable with a first monitoring device and switching data traveling along the primary network cable to a secondary network cable when a fault is detected in the primary network cable, wherein a link status output on the first monitoring device indicates the status of the primary network cable.

31. The method of claim 30, wherein the switching of data traveling along the primary network cable to the secondary network cable is accomplished without any active management of monitoring or switching apparatus.

32. The method of claim 30, wherein the monitoring of the primary network cable is accomplished with no programming and no software.

33. The method of claim 30, further comprising monitoring the secondary network cable with a second monitoring device, wherein a second link status output on the second monitoring device indicates the status of the secondary network cable.

34. The method of claim 33, wherein the second monitoring device is a PHY.

35. The method of claim 30, wherein the first monitoring device is switched to monitor the secondary network cable and no longer monitors the primary network cable when the data is switched to travel along the secondary network cable, wherein the first monitoring device link status output indicates the status of the secondary network cable.

36. The method of claim 35, further comprising switching the data traveling along the secondary network cable back to the primary network cable when a fault is detected by the first monitoring device in the secondary network cable.

37. The method of claim 30, wherein the first monitoring device is a PHY.

38. A method of administering a redundant cable system comprising:
monitoring primary and secondary network cables with first and second monitoring devices, respectively; and
switching a data stream route from the primary network cable to the secondary network cable when the first monitoring device indicates a fault in the primary network cable and the second monitoring device indicates no faults in the secondary network cable.

39. The method of claim 38, wherein the faults in the primary and secondary network cables are indicated solely by link status outputs on each of the first and second monitoring device s.

40. The method of claim 39, wherein the first and second monitoring devices are PHYs.

41. The method of claim 38, wherein the switching of the data stream along the primary network cable to the secondary network cable is accomplished without any active management of monitoring apparatus.

42. The method of claim 38, wherein the monitoring of and switching from the primary network cable are accomplished with no programming and no software.

43. The method of claim 38, further comprising switching the data stream route from the secondary network cable to the primary network cable when the second monitoring device indicates a fault in the secondary network cable and the first monitoring device indicates no faults in the primary network cable.

44. A circuit enabling the routing of data to a primary or secondary network cable connected to primary and secondary nodes comprising:
a first PHY for monitoring link status of the primary network cable;
a complex programmable logic device (CPLD) for monitoring the link status reported by the first PHY; and
a switch for routing the data to one or the other of the primary or secondary network cables.

45. The circuit of claim 44, further comprising a hub device for re-transmitting data from a local network port, the hub having a primary and secondary port for both receiving incoming data and sending outgoing data.

46. The circuit of claim 45, further comprising a second PHY for monitoring the link status of the secondary network cable and secondary node.

47. A method of creating a cable redundancy comprising:
monitoring a primary network cable with a first PHY and switching data traveling along the primary network cable to a secondary network cable when a fault is detected in the primary network cable, wherein a link status output on the first PHY indicates the status of the primary network cable.

48. The method of claim 47, wherein the switching of data traveling along the primary network cable to the secondary network cable is accomplished without any active management of monitoring or switching apparatus.

49. The method of claim 47, wherein the monitoring of the primary network cable is accomplished with no programming and no firmware.
